(19) United States
(12) Patent Application Publication
(10) Pub. No.: US 2018/0261146 A1
(43) Pub. Date: Sep. 13, 2018

(54) VIDEO GLASSES

(71) Applicant: MEDINTEC B.V., Oosterbeek (NL)

(72) Inventors: Reinier VAN 'T HOOFT, Oosterbeek (NL); Arno BALTUSSEN, Oosterbeek (NL)

(21) Appl. No.: 15/761,892

(22) PCT Filed: Sep. 23, 2016
(86) PCT No.: PCT/EP2016/072706

§ 371 Date: Mar. 21, 2018

(30) Foreign Application Priority Data
Sep. 23, 2015 (EP) 15186391.7

(51) Int. Cl. G09G 3/20; H04R 1/02; G10L 21/0232; G01R 33/28

(52) U.S. Cl. CPC G09G 3/2092; H04R 1/028; G09G 3/36; G01R 33/283; G10L 21/0232

(57) ABSTRACT

A headset unit comprising (i) a pair of goggles with an implemented video functionality and (ii) ear units, wherein the headset unit is configured to substantially enclose the eyes of a human during use of the headset unit to prevent external light reaching the eyes of the human wearing said headset unit, wherein the ear units are configured to enclose the ears or to be plugged into the ears, wherein the ear units are configured to provide a sound signal to the ears, wherein the goggles comprise display sections, wherein the headset unit further comprises independently adaptable first optics for dioptric adjustment, wherein the display sections and the first optics are configured to provide images to the eyes of the human wearing said headset unit, wherein the headset unit further comprises an internal control system configured to control image content displayed on the display sections.

### FIELD OF THE INVENTION

The invention relates to a headset unit, a system including such headset unit, and a sensor setup which may functionally be coupled with the headset unit, and which may be used in MRI applications.

### BACKGROUND OF THE INVENTION

Presently, there is large interest in virtual reality glasses. Similar type systems are also proposed for medical applications. For instance, US2010/0231483 describes a system for use in an MRI device used with a subject comprising (a) an interface comprising a microprocessor for receiving a video input and an audio input, and for receiving subject generated sound input and subject generated control input; (b) a visual display for receiving from the interface the video input and for displaying to the subject visual images, the video display comprising left and right displays and first adjustment means for adjusting the distance between the left and right displays, each display comprising (i) an OLED for receiving the video input and transmitting video images, (ii) a prism receiving the video images from the OLED, and (iii) second adjustment means for adjusting the distance between the prisms and the OLED; (c) a sound suppression circuit in the interface for suppressing sound emanating from the MRI device by generating a sound suppression signal; (d) a sound transmission system wearable by the subject, wherein the sound transmission system receives the audio input and the sound suppression signal from the interface; (e) a microphone system for receiving subject generated sound for transmission to the interface as subject generated sound input; (f) a subject controllable input device for providing subject inputs to the interface; and (g) a subject monitor receiver in the interface for receiving physiological information about a subject, wherein the system is sufficiently shielded that it can be used in an MRI room. This document also describes that many medical procedures cause increased anxiety in subjects due to the unfamiliarity with the location where the procedure is being conducted and noise and other environmental factors. For example, magnetic resonance imaging (“MRI”) systems and functional magnetic resonance imaging (“fMRI”) systems are widely used for diagnosing the physical and/or mental condition of subjects. They are also used as a research tool for determining the effect of various stimuli on brain activity. For research purposes, it is desirable that audio and/or video stimuli can be provided to a subject undergoing MRI. It is desirable to distract a subject from the MRI process, which can be claustrophobic.

WO2014/124707 describes a variable-power lens comprising first and second lens elements one behind the other along an optical axis of the lens. Each element has opposed planar and curved surfaces such that the thickness of each element in a direction parallel to the optical axis varies in a direction transverse to the optical axis. The elements are relatively moveable in the transverse direction, whereby the power of the lens may be varied. The elements are arranged such that the curved surface of the first element is adjacent the second element and the planar surface of the first element bears a diffractive pattern.

US2014/340389 describes a system, method, and computer program product for producing images for a near-eye light field display. A ray defined by a pixel of a micro display and an optical apparatus of a near-eye light field display device is identified and the ray is intersected with a two-dimensional virtual display plane to generate map coordinates corresponding to the pixel. A color for the pixel is computed based on the map coordinates. The optical apparatus of the near-eye light field display device may, for example, be a micro lens of a micro lens array positioned between a viewer and an emissive micro display or a pinlight of a pinlight array positioned behind a transmissive micro display relative to the viewer.

US2015/049390 describes a method for displaying a near-eye light field display (NELD) image. The method comprises determining a pre-filtered image to be displayed, wherein the pre-filtered image corresponds to a target image. It further comprises displaying the pre-filtered image on a display. Subsequently, it comprises producing a near-eye light field after the pre-filtered image travels through a micro lens array adjacent to the display, wherein the near-eye light field is operable to simulate a light field corresponding to the target image. Finally, it comprises altering the near-eye light field using at least one converging lens, wherein the altering allows a user to focus on the target image at an increased depth of field at an increased distance from an eye of the user and wherein the altering increases spatial resolution of said target image.

### SUMMARY OF THE INVENTION

Video glasses described in the prior art may suffer from a plurality of disadvantages. US2010/0231483 mentions e.g. that existing systems that can provide stimuli suffer from one or more deficiencies, such as inability to be used with high power MRI systems such as those operating at 7 Tesla, discomfort for the subject, and limited capability of the interface system in providing input to the subject and receiving output from the subject. This document further indicates that, for example, orthopedic arthroscopic procedures (i.e., knee scope removing arthritic tissue, spurs, etc.) often leave the subject awake with a combination of local and axial blocks administered instead of general anesthetics. Being awake in the operating room, with the noises of saws, suction, and other surgical instruments, in addition to the anxiety building feel of the room can cause emotional discomfort to many subjects. Standard earphones and visual display eyewear do not provide sufficient blocking of operating room noise and can increase subject anxiety and fear by not being adjustable by the subject while the medical procedure is performed. Further, prior art headsets may be uncomfortable or may need complicated optics or optical pathways. For e.g. MRI applications, this is not desirable.

It was found that many prior art video glasses have disadvantages in terms of bulky dimensions, easy of adaptability, reality experience, and optical quality of the images. Hence, it is an aspect of the invention to provide an alternative solution, which preferably further at least partly obviates one or more of above-described drawbacks.

In a first aspect, the invention provides a headset unit (“video glasses”) comprising (i) a pair of goggles with an implemented video functionality and optionally (ii) ear units, wherein the headset unit is configured to substantially enclose the eyes of a human during use of the headset unit to prevent external light reaching the eyes of the human wearing said headset unit, wherein the (optional) ear units are configured to enclose the ears or to be plugged into the ears, wherein the ear units are configured to provide a sound signal to the ears, wherein the goggles comprise (one or more) display sections, wherein the headset unit further especially comprises independently adaptable first optics for dioptric adjustment, wherein the display sections and the first optics are configured to provide images to the eyes of the human wearing said headset unit, wherein the headset unit may further comprises an internal control system configured to control image content displayed on the display sections.

In yet a further aspect, the invention provides a headset unit comprising (i) a pair of goggles with an implemented video functionality and (ii) optionally ear units, wherein the headset unit is configured to substantially enclose the eyes of a human during use of the headset unit to prevent external light reaching the eyes of the human wearing said headset unit, wherein the (option) ear units are configured to enclose the ears or to be plugged into the ears, wherein the(optional) ear units are configured to provide a sound signal to the ears, wherein the goggles comprise (one or more) display sections, wherein the headset unit comprises first optics and optional second optics, wherein the display sections, the first optics and the optional second optics, are configured to provide images to the eyes of the human wearing said headset unit, wherein the first optics or the optional second optics especially comprise Fresnel lenses.

With such headset unit it is possible to have a good reality experience due to a good display of images. Further, such headset unit may be relatively compact, while still being adaptable to the desired dioptrics. Dioptric correction or dioptric adaptation is the expression for the adjustment of the optical instrument to the varying visual acuity of a person's eyes. It is the adjustment of one lens to provide compatible focus when the viewer's eyes have differing visual capabilities. The invention allows “near eye” applications. For instance, the device may be configured such that during use a distance between the retina and display is especially up to about 80 mm, such as up to 70 mm, like in the range of 30-70 mm, like in the range of 40-65 mm.

Further, such headset unit is not necessarily controlled from external (though this is not excluded). The internal control can be used to control image content displayed on the display sections (see further also below). Further, such headset unit can be used to isolate the user from the surroundings, as light from external from the headset may be substantially blocked and also sound from external from the headset may substantially be blocked by enclosing the ears with the ear units and/or ear units that can be plugged into the ear.

As will further be elucidated below, in specific embodiments the display sections each comprise nxm pixels, wherein n and m independently are especially at least 600, and wherein k and l independently are especially at least 150.

As will also further be elucidated below, in specific embodiments the headset unit further comprises said second optics, wherein the second optics comprises two sets of k×l micro lens arrays, comprising micro lenses, configured downstream of said display sections, respectively.

As will further be elucidated below, in specific embodiments the headset unit comprises independently adaptable first optics for dioptric adjustment, and especially the independently adaptable first optics for dioptric adjustment each comprise a set of Alvarez lenses.

As will also further be elucidated below, in specific embodiments the headset unit further comprises an internal control system configured to control image content displayed on the display sections.

As will further be elucidated below, in specific embodiments the Fresnel lenses have a focal length selected from the range of 25-45 mm, may especially have a number of concentric grooves selected from the range of 65-90, and the Fresnel lenses may especially comprise poly methyl methacrylate.

As will yet further be elucidated below, in specific embodiments the first optics comprise Alvarez lenses, wherien the Fresnel lenses are integrated.

Yet further, in embodiments the headset unit is a single unit which can be arranged on the head, thereby enclosing the eyes and isolating the ears, whereas some prior art solutions use physically independent units for enclosing the eyes and sound applications. Hence, the headset unit is especially suitable for MRI applications, e.g. to provide to a human images and sound to distract the person. However, other medical applications are also possible (see below). Herein, it is often referred to an MRI application. However, the present invention may also be used in combination with tomography. Hence, unless indicated otherwise or clear from the context, instead of MRI also tomography may be read. Tomography may e.g. refer to CT (X-rays), SPECT (gamma rays), MRI (radio-frequency waves), ERT (Electrical Resistance), PET (electron-positron annihilation), electrons Electron tomography or 3D TEM, muon tomography, atom probe tomography, magnetic particles magnetic particle imaging, and fluid flow hydraulic tomography, etc.

Other applications, especially in the medical field may in general include patient distraction during medical examinations or medical treatments (prior and during surgery with full or local anesthetics; during chemotherapy; during dental treatments, etc.). Further, the headset unit may also be applied as (post-CVA (cerebrovascular accident)) rehabilitation tool or as viewing tool for clinicians. Yet further applications may include neuro rehabilitation, phobic disorder treatment/management. Alternatively or additionally, the headset unit may also be applied for non-medical applications, such as for training, security applications, gaming, neuro marketing, and lie-detection, etc. Further, the headset can be used for 3D presentations.

In a specific embodiment, the display sections each comprise n×m pixels, wherein n and m independently are at least 100, especially n and m are independently at least 200, especially at least 400, such as even at least 800, like at least 1200. This may provide the desired resolution for the images. Especially, each display section comprises a display selected from the group consisting of a liquid crystal display (LCD), liquid crystal on silicon (LCoS), a light emitting diode (LED) display, an organic light emitting diode (OLED, including e.g. a stack OLED) display, and an active-matrix organic light-emitting diode (AMOLED) display. The two display sections may optionally be comprised in a single display including two separate display sections. Between the display sections, there may be a part without pixels or with inactive pixels. The term “display sections” especially refers to a first display section configured for one of the eyes of a user and a second display section configured for the other one of the eyes of a user. During use, the user receives light only via the display sections, as the eyes are prevented by the headset unit from receiving external light.

Further, during use, a first display section may be configured to provide visual content to one eye and the other display section may be configured to provide visual content to the other eye. The headset unit, the headset unit comprising system, or the control system may especially be configured to provide surround vision images or 3D images to the display sections. The term “user” herein especially refers to the human wearing the headset and which during use receives content via the display sections and/or sound via the ear units.

Especially, the headset unit comprises adaptable first optics. Alternatively or additionally, the headset unit comprises second optics. The first optics and the second optics are configured downstream of the display. The first optics may e.g. comprise an Alvarez lens. The second optics may include one or more of a micro-lens array and a Fresnel lens. The first optics may especially be used for adaptation to the dioptrics of the eye of the user and may therefore especially be adaptable. The second optics are especially configured to collimate the light of the pixels of the display. Embodiments of the first optics and of the second optics are further described below. The term “first optics” may refer in embodiments to two first optics, with one (“first first optics”) functionally coupled to a first display section and the other (“second first optics”) functionally coupled to a second display section. Likewise, the term “second optics” may refer in embodiments to two second optics, with one (“first second optics”) functionally coupled to a first display section and the other (“second second optics”) functionally coupled to a second display section.

In yet a further embodiment, the headset unit further comprises two sets of k×l micro lens arrays, comprising micro lenses, configured downstream of said display sections, respectively, wherein k and l independently are at least 100, such as at least 150, like especially at least 200, especially k and l are independently at least 400, such as even at least 800, like at least 1200.

Each display section pixel may be optically aligned with a micro lens. However, alternatively two or more display section pixels may optically be aligned with a single micro lens. Hence, a main direction of the display section pixel light and an optical axis of the micro lens may substantially coincide. For instance, when using RGB pixels, a set of RGB pixels may be aligned with a single micro lens. Hence, in embodiments n=k and m=l.

The terms “upstream” and “downstream” relate to an arrangement of items or features relative to the propagation of the light from a light generating means (here the display section), wherein relative to a first position within a beam of light from the light generating means, a second position in the beam of light closer to the light generating means is “upstream”, and a third position within the beam of light further away from the light generating means is “downstream”.

Micro lens arrays are known in the art and may e.g. be made from polymeric materials, 3D printing, scanning (excimer) laser ablation, etc. etc. the dimensions of the pixels of the display sections may be in the range of 1-5 μm. Further, the dimensions, such as width and length or diameter of the micro lenses may be in the range of 0.1-10 μm, such as 0.2-5 μm.

Fresnel lenses are also known in the art, and can be used to collimate the light of the pixels of the display. Downstream from each display, a Fresnel lens may be configured. Also combinations of Fresnel lenses and micro-lens arrays may be provided.

The second optics may especially be configured downstream from the display and upstream from the first optics. However, in other embodiments, the first optics and second optics may be integrated. For instance, when using Alvarez lenses, the second optics may be configured at one side of a lens element of the Alvarez lens (which especially comprises at least two lens element (lenses)), and may optionally even be 3D printed at one side of a lens element of an Alvarez lens. The second optics, such as the micro-lens array or the Fresnel lens, may in embodiments be 3D printed on a (light transparent) substrate, such as e.g. a lens element of an Alvarez lens, or another substrate. Lenses and refractive structures can be printed with dimensions down to 100 μm, or even smaller. Further, the second optics may be provided as flexible optics and/or as curved optics. In this way, also a curvature may be provided in one or two directions. For instance, the second optics may be printed on a bendable polymeric substrate or on a bended polymeric substrate. Transparent materials that can be 3D printed or that can be used as transparent substrate are known in the art, and include amongst others polysiloxanes (see also DE 102005050185).

Herein, the phrases like “n and m are independently” indicate that n and m may in principle be chosen independent of each other. In general however, the ranges of n and m will be between about 10:1-1:10, such as 8:1-1:8, such as about 16:9. Even, n and m may be chosen different for the different goggle elements (for left eye and right eye), though this will in general not be the case. Likewise, the ranges of k and l will be between about 10:1-1:10, such as 8:1-1:8, such as about 16:9. Even, k and l may be chosen different for the different goggle elements (for left eye and right eye), though this will in general also not be the case. Especially, the micro lenses, or other second optics, are configured to provide a fixed focal distance to the eyes (i.e. between the display and the retina) of the human wearing the headset unit. Optionally, however, this distance is not fixed (see further below).

Goggles or safety glasses are often used as protective eyewear which especially enclose or protect the area surrounding the eye in order to prevent particulates, water or chemicals from striking the eyes. Herein, the goggles are especially used to shield the eyes from light from external of the goggles. Hence, in fact the goggles are, as known to the person skilled in the art, goggles that are configured to block substantially all light from external of the goggles to prevent external light reaching the eyes.

Especially useful for dioptric adjustment appear Alvarez lenses. Hence, in a further embodiment the independently adaptable first optics for dioptric adjustment each comprise a set of Alvarez lenses. Hence, both goggle elements may include Alvarez lenses which may be independently controllable. Such lenses have the unique ability to be relatively thin and to be able to adapt relatively easy the dioptrics.

Amongst others, the term “independently adaptable first optics” may especially indicate that the optics may be adapted for each goggle, i.e. each eye, independently. Further, the adaptability may refer to an axial translation (i.e. closer or further away from the eye) or a translation perpendicular to an axis perpendicular to the eye (i.e. no substantial axial translation, but a translation perpendicular to an optical axis of the eye). Optionally, the adaptability may also include a rotation along the optical axis of the eye. For a set of Alvarez lenses, the adaptability may also include a translation of the Alvarez lenses relative to each other. Hence, in embodiments the herein described Fresnel lenses may independently be adapted to accommodate the dioptrics of the respective eye. As indicated above, the adaptability may be chosen in dependence of the eye. Hence, the invention may allow axial and/or lateral adjustment, especially independently for each goggle element.

Suitable first optics for use in this invention are amongst others described in U.S. Pat. No. 3,305,294 (Alvarez), which is herein incorporated by reference, and WO2006025726 (Van der Heijde), which is also herein incorporated by reference.

The former document describes amongst others a variable-power lens comprising two lens elements arranged in tandem, one behind the other along the optical axis of the lens, and means for moving at least one of said elements relative to the other in a direction transverse to the optical axis of the lens, each of said elements having polished surfaces with one of the surfaces being a regular surface of revolution and an optical thickness variation parallel to the optical axis less than one-half the lens diameter, and the optical thickness of each element being substantially defined by the formula

A(xy²+⅓x³)+Dx+E

wherein D is a constant representing the coefficient of a prism removed to minimize lens thickness and may be zero, E is a constant representing lens thickness at the optical axis, x and y represent coordinates on a rectangular coordinate system centered on the optical axis and lying in a plane perpendicular thereto, and A is a constant representing the rate of lens power variation with lens movement in the x direction and being positive for one lens element and negative for the other lens element. Further embodiments of U.S. Pat. No. 3,305,294 may also be of relevance.

The latter document describes amongst others an artificial intraocular lens, comprising two lens elements, arranged one behind the other along the optical axis (Z) of the lens (L), wherein at least one of the lens elements is movable relative to the other transversely to the optical axis (Z) of the lens (L), wherein the optical thicknesses of the lens elements (1, 2) are such, that the power of the lens changes by transversal displacement of at least one of the lens elements relative to the other. Especially, the lens is arranged substantially according to the variable power lens of American patent U.S. Pat. No. 3,305,294. In a further embodiment of WO2006025726, such artificial intraocular lens is provided, wherein optical thicknesses of the two lens elements correspond substantially to those of the elements of the variable power lens of Luis W. Alvarez of the American patent U.S. Pat. No. 3,305,294, such as such artificial intraocular lens, wherein the optical thickness t of each of said lens elements (1, 2) is substantially defined by the following formula:

T=A(xy²+⅓x³)+Bx²+Cxy+Dx+E+F(y)

wherein B, C, D and E are constants that may be given any practical value, including zero, and F(y) is a function that is independent of x and may be zero, x and y represent coordinates on a rectangular coordinate system centered on the optical axis and lying in a plane perpendicular thereto, and A is a constant representing the rate of lens power variation with lens movement in the x direction. Further, embodiments of WO2006025726 may also be of relevance. Optionally, the Alvarez lenses are provided from a flexible material, allowing some further curvature of the lenses, like the curvature of the display sections.

The headset unit may comprise means for moving at least one of the lens elements relative to the other in a direction transverse to the optical axis of the lens. Such means may include manual means, such as a lever configured to be moved (translated) wherein the movement induced moves the at least one of the lens elements by moving a lever. However, the means may also include electrical means (herein also indicated as electronic device). Yet alternatively, the means may also include hydraulic means. Also electrical and/or hydraulic means may be configured to be controlled (i.e. induce the desired change of the lens element(s)) by a manual action such as touching a button or turning a knob.

Above, the first optics are especially described in relation to Alvarez lenses. These lenses may allow amongst other dioptric correction. For correction, amongst others dioptric adaptation, means for moving the Alvarez lenses (or lens elements) may be applied. Optionally, also second optics may be applied, including one or more of micro lense optics (micro lens arrays) and Fresnel lenses. Alternative to the Alvarez lenses, also micro lens arrays and/or Fresnel lenses may be applied. Such optics may also be moved with the means for moving, especially amongst others for dioptric adaptation. Hence, in another embodiment the first optices are selected from the group consisting of micro lens arrays and Frensnel lenses (or, alternatively defined: only second optics are applied).

Hence, the headset unit may also include a user interface. This user interface may thus be physically associated with the headset unit. Further, the user interface is especially functionally coupled with the control system. Alternatively or additionally, a user interface may be provided, configured remote from the headset, but configured in functional connection with the control system. For instance, a headset unit comprising system may comprise the headset unit and a user interface. The user interface may be configured for controlling (such as via the control system) one or more of the means for moving, audio (audio information) and video (video information). In this way, the user may be able to control the settings of the first optics and/or second optics. Alternatively or additionally, in this way the user may be able to control the content displayed on the display sections. For instance, the user may select between movies, repeat part of a movie, or select between a movie and camera images (when a camera or more cameras are available), select brightness, contrast, etc. etc. Yet alternatively or additionally, in this way the user may be able to control the audio content, like controlling audio volume, treble/bas settings, etc. etc. The user interface, when not integrated in the headset unit may e.g. be comprised by a handheld device. In embodiments, the user interface comprises a voice user interface (VUI).

Alternatively or additionally, the means for moving at least one of the lens elements may be controlled by a control system (for moving at least on of the lens elements). For instance, before using the goggles the eyes may be measured to provide input data for the control system and/or eye data may be provided to the control system (without a measurement before use). Eye data (such as Hyperopia or Myopia) may be known to the user. The control system may be configured to store the eye data for a user. Based on such input, the control system may control the the means for moving at least one of the lens elements, to provide the most suitable setting for the user. The control system (see below) is not necessarily completely comprised by the headset. As indicated above, a control system for controlling the means for moving at least one of the lens elements is even not necessary, as also means for manually controlling at least one of the lens elements may be used. However, in general at least part of the control system for moving (controlling) at least one of the lens elements may be comprised by the headset unit. Hence, in specific embodiment the headset unit further comprises an electronic device configured to control the dioptric adjustment of the first optics. This electronic device may be the control system or may be comprised by the control system (for controlling the means for moving at least one of the lens elements).

Above, the means for moving are especially described in relation to moving at least one of the lens elements relative to the other in a direction transverse to the optical axis of the lens. The headset unit may more in general comprise a means for controlling the first optics. Assuming an x-axis to be parallel to a line from ear to ear, an y-axis to be perpendicular to this line, and being parallel to a line perpendicular to the eyes, and a z-axis, being perpendicular to the x-axis and y-axis, and being parallel to a line through the body of a straight standing person from top to bottom, this may include one or more movements selected from the group consisting of (a) a movement in a direction along the x-axis, the y-axis and the z-axis, especially along the y-axis, as the y-axis direction movement may assist in focusing and defocusing. Alternatively or additionally, this may in the case of an Alvarez lens thus especially include moving at least one of the lens elements relative to the other in a direction transverse to the optical axis of the lens. Hence, in the case of Alvarez lenses, optionally the means may be configured to adapt only one of the Alvarez lenses, without adapting the other, and vice versa. The above described embodiments described especially in relation to moving at least one of the lens elements relative to the other in a direction transverse to the optical axis of the lens, may also apply to the means for moving in general, as this means may be configured to move, or more in general, to control the first optics and/or optional second optics. In an embodiment, a separate external sensor device may be used to generate the relevant eye data. An example of such external sensor device may e.g. include an autorefractor or aberrometer, as known in the art. Such devices may measure automatically relevant eye data. Alternatively or additonally, an App may be used to provide the relevant eye data. The control system is configured to relate these eye data to the most suitable dioptric adjustment. In yet a further embodiment, the headset unit comprises a sensor for generating eye data and controlling, with the control system, based on these eye data the means for moving at least one of the lens elements. For instance, each goggle element may comprise such sensor for generating eye data. Based on these eye data, the means for moving at least one of the lens elements may be used to control the first optics. The sensor(s) to use for generating the relevant eye data for controlling the dioptric adjustment may include e.g. an IR sensor. The headset (or control system) may be configured to sense with the sensor the eye data once, such as directly or shortly after arranging the headset to the head. However, optionally, there may also be a continous adaptation. For instance, the sensor may sense each 10 minutes. Hence, the IR sensor may be used for automatical accomodation of the optics (one or more of the first optics and second optics).

Combinations of two or more of the above defined embodiments may also be applied. Further, the the dioptric adjustment may be different for each eye. Hence, the means for means for moving at least one of the lens elements may include means (or a plurality of means) to independently moving at least one of the lens elements for each of the goggle elements. The Alvarez lenses are configured downstream of the display sections. The optional micro lens arrays as mentioned above are also configured downstream from the display sections and configured upstream from the optional Alvarez lenses.

Alternatively or additionally, the means for moving may be configured to move the second optics, especially in a direction to or away from the eyes (herein also indicated as y-direction. In such instance, dioptric adjustment may alternatively or additionally be obtained by the second optics. Therefore, in specific embodiments, one may only use the second optics, and renounce the first optics (especially being Alvarez lenses). In other words, one could define that the adaptable first optics are selected from the group consisting of micro-lens arrays and Fresnel lenses, and the headset unit further comprises a means to move these first optics at least in a direction to or away from the eyes, wherein especially this means may independently control the first optics downstream from each display section, respectively.

Hence, the means for moving may be configured to move the first optics. The movement may include one or more of (a) a movement perpendicular to an optical axis, and (b) a movement parallel to an optical axis. Further, the movement may include one or more of (i) moving both the first optics functionally coupled with a first display section and first optics functionally coupled with a second display section, and (ii) moving only one of the first optics functionally coupled with a first display section and first optics functionally coupled with a second display section. In the latter embodiment, the first optics may be moved relative to each other.

Yet further, the means for moving may be configured to move the second optics. The movement may include one or more of (a) a movement perpendicular to an optical axis, and (b) a movement parallel to an optical axis. Further, the movement may include one or more of (i) moving both the second optics functionally coupled with a first display section and second optics functionally coupled with a second display section, and (ii) moving only one of the second optics functionally coupled with a first display section and second optics functionally coupled with a second display section. In the latter embodiment, the second optics may be moved relative to each other from 30-80 mm.

An advantage of the herein described embodiment(s) is that a relatively compact headset unit may be provided. In a specific embodiment, the headset unit has a maximum depth of 10 cm, such as in the range of 4-10 cm, like at maximum 8 cm.

Nevertheless, the herein described embodiments also allow a relative wide view. Especially, the display sections are configured in the headset unit to provide a field of view angle (θ) to the eyes of at least 60°, such as at least 70°, like at least 80°, such as in the range of 60-120°, like even the range up to about 160°, even up to about 180°. This wide angle may e.g. be obtained with a plurality of display sections for each goggle element, with two or more display section configured relative to each other under an angle unequal to 180°. In this way, the display sections of a goggle element partly surround the eyes (or orbits).

Alternatively or additionally, the display sections comprise curved displays, having at least curvatures in one dimension. These curvatures are especially chosen such, that when the headset unit is used on a human's head, the curvature follows at least partly the curvature of a line over the eye from a first corner of an eye to a second corner of the same eye (this line is indicated as first eye curvature line). Hence, the curvature (“first curvature”) of the display sections may substantially be parallel to a first plane parallel to the eye which plane comprises the first eye curvature line and which plane has a curvature in only one dimension. Optionally, the display sections may include a second curvature in a second dimension, perpendicular to the first dimension. In use, the first curvature may be substantially parallel to a plane following about the curvature from the head from ear to nose and the second curvature may substantially be parallel to a plane following about the curvature from the eye from the lower eyelid to the upper eyelid. Especially, the first curvature is available and the second curvature may be optional. In a specific embodiment, the display sections comprise flexible or curved displays. Especially suitable displays comprise one or more of organic light emitting diode (OLED) display, an active-matrix organic light-emitting diode (AMOLED) display, etc., because these LED based displays do not need backlighting.

When the display section(s) include an angle or curvature, especially also the optional micro lens array will have a similar or even conformal angle or curvature, respectively. Optionally, the micro lens arrays may be in physical contact with the (respective) display section(s). Optionally, also the Alvarez lenses may include an angle or curvature, respectively, similar or conformal to the angle or curvature of the display section.

In addition to the goggle features of the headset unit, the headset unit also includes ear units are configured to enclose the ears or to be plugged into the ears, wherein the ear units are configured to provide a sound signal to the ears. In this way, e.g. a patient may be distracted from sound of e.g. apparatus and be attracted to e.g. one or more of music, sound signals related to images provided to the display sections, and anti sound (anti noise). In a specific embodiment, the ear units are configured to provide sound to the human wearing the headset unit, wherein the internal control system (see further below) is configured to control the sound provided by the ear units. The ear units are especially configured to isolate the meatus from sound from external of the ear units. In an embodiment, the ear units comprise units that fully enclose the respective ears.

A first ear unit may, during use, be configured to provide sound to one ear and a second ear unit may, during use, be configured to provide sound to the other ear. The headset unit, the headset unit comprising system, or the control system may especially be configured to provide stereophonic sound to the ear units.

At least, there is one type of signal generation with the headset unit, i.e. the display of images with the display sections. Optionally, also sound signals may be generated with the headset unit, i.e. to provide sound to the human wearing the headset unit. Further, optionally, a further type of signal that may be generated with the headset is a sensor signal from a sensor configured for generating eye data. The internal control system may generate one or more of these signals (images, sound) or use these signals (eye data). Further, the internal control system may use memory data, such as eye data for controlling the first optics.

The internal control system may be independent of any control system. In such embodiment the headset unit substantially only needs a source of electrical power, which may even be incorporated in the headset unit (internal battery), or which may be worn by the user, or which may e.g. be remote from the user (such as external from an MRI), and optionally e.g. a memory carrier for images and/or sound. The internal control system may partly be independent, and partly dependent from an external control system. For instance, images and/or sound may be provided from external from the headset unit, guided via a wire (electrical wire and/or fiber optic wire) or wireless to the headset unit and may be displayed and/or may be provided as sound, respectively. However, e.g. adaptation of the first optics may be controlled by the internal control system (e.g. together with a sensor). In such embodiment, the internal control system may be configured as receiver for receiving data and transmitting and/or translating the data from the external control system into one or more of images, sound and first optics settings. Especially in these embodiments, but not exclusive for these embodiments, the headset unit may further comprise a memory configured to store one or more of video information and audio information, wherein the memory is functionally coupled with the control system.

In yet a further embodiment, the internal control system may substantially be dependent. For instance, all images and/or sound is received from external from the headset unit, i.e. from the external control system, and the eye data or concomittant settings for the first optics may also be provided by the external control system. The internal control system may then transmit and/or translate the data from the external control system into images, sound and first optics settings. In such embodiment, the internal control system may essentially be configured as receiver. The term “control system” may refer to the internal control system, the external control system, a combination of the internal control system and external control system being functionally coupled (which may in fact include a control system having the functionalities of the internal control system and external control system).

The visual content (images) displayed on the display sections may especially include movies, including commercials, training movies, news, etc. etc.

In yet a further embodiment, the headset unit may further comprise a sensor configured for sensing a user parameter. This user parameter may optionally include the above mentioned eye data for use to determine the first optics settings. Hence, the sensor may be configured for eye monitoring and/or eye tracking. However, alternatively or additionally the sensor may be configured to measure one or more of temperature, skin humidity (skin conductivity), concentration, heartbeat, saccade or micro-saccade per individual eye, etc. etc. The term “sensor” may also refer to a plurality of (different) sensors. The sensor information may be used by the internal and/or external control system to (further) control one or more of the images, sound and optionally first optics settings. For instance, when the user appears to be nervous or stressed, relaxing images and/or sound may be provided. However, the sensor information may also be used for other purposes, such as for research. For instance, the reaction of a user on images and/or sound may be used for research on commercials, education, training, information furnishment, etc. etc. Optionally, this may be combined with e.g. MRI information. However, this sensor information may also be used for medical research, e.g. also in combination with e.g. (f)MRI information. Hence, the external control system may be comprised by a medicial system or may communicate with a medical system such as an MRI (or tomography, or other (see also above). The sensor, or more generally the control system, may be configured to sense (or have sensed) with the sensor continously. For instance, the sensor may sense each 10 minutes, or more frequently. Alternatively, the sensor, or more generally the control system, may be configured to sense only once, especially at a start of the use of the heatset unit. Especially however, the sensor or more generally the control system, may sense substantially continuously, such as each 10 minutes, or more frequently. In this way, a parameter (such as mentioned above) can be monitored.

Therefore, in an embodiment the headset unit further comprises a sensor configured to sense eye behavior of one or more eyes of the human wearing the headset unit, and/or one or more other user parameters, wherein the sensor is configured to provide a corresponding sensor signal to the control system. Especially, the sensor comprises a source of IR radiation and an IR detector, wherein the source of IR radiation is configured to provide IR radiation to one or more eyes of the human wearing the headset. This IR sensor may be used for providing eye data for controlling the first optics (see also above) and/or may be used to provide other eye data such as eye movement, pupil dimensions, etc. etc. as (further) user parameter(s).

When signals from the headset have to be provided to an external control system, the headset may be coupled wired or may be coupled wireless. In a specific embodiment, the headset unit further comprises a transmitter unit, configured to transmit a signal from a sensor or the internal control system to an external control system and/or to receive one or more of video information and audio information from an external control system for displaying on the display sections and for providing to the ear units, respectively. A sensor signal may directly be transmitted or may be transmitted after being processed by the internal control system.

Hence, especially the internal control system is functionally connectable to an external control system. During use, the internal control system may thus be connected with the external control system.

The external control system may be comprised by a headset unit comprising system. The term headset unit comprising system refers to a system wherein the headset unit is functionally coupled with one or more other devices. For instance, the headset unit comprising system may in embodiments include a computer and a headset unit, wherein these can be functionally coupled. Other embodiments of a headset unit comprising system include sensor setups.

Therefore, the invention also provides in an aspect a sensor setup comprising a sensing apparatus configured to sense a body part of a human, the sensor setup further comprising a control system configured to control the headset unit as defined herein. In an embodiment the sensor setup comprises an MRI device or a tomography apparatus as sensing apparatus. For instance, the body part to be sensed may be the brains (or a specific part thereof), but other parts may not be excluded. As indicated above, the control system may be comprised by the sensing apparatus, or e.g. there may be a control system controlling both the sensing apparatus and the headset unit, etc. Especially, the sensing apparatus is configured to sense a body part of a human as function of one or more of (i) video information and (ii) audio information, displayed on the display sections and provided to the ear units, respectively, during use of the sensor setup and headset unit. Hence, the sensing apparatus may include embodiments wherein the headset unit is used for research on a body part of the human, for instance together with an MRI or tomography. However, the sensor setup may also include a sensing apparatus to sense a body part of a human, wherein the headset unit may essentially not be used in the sensing of the body part but for other purposes, such as relaxation of the human (during the sensing of the body part).

In a specific embodiment, the control system is configured to suppress noise generated by the sensing apparatus by providing a sound suppression signal to the ear units. In yet a further specific embodiment the control system is configured to suppress noise external from the headset by providing a sound suppression signal to the ear units. The noise external from the headset may be any sound generated by the sensing apparatus and/or or devices or human made sounds.

In yet a further aspect the invention provides a sensor setup comprising a sensing apparatus configured to sense a body part of a human, the sensor setup further comprising a control system configured to control the headset unit according as defined herein and the sensing apparatus, wherein the headset unit comprises a sensor to measure a user parameter of a user wearing the headset unit, and wherein the control system is configured to control the sensing apparatus as function of the user parameter. For instance, the sensing apparatus may execute other movements, or more relaxed movements, or other measurements, or more relaxed measurements, or temporarily stop, etc. etc. when a person being sensed by the sensing apparatus appears not to be relaxed, as sensed with the sensor by the headset unit. Likewise, sensing may be intensified, etc., when the person is more relaxed (as sensed with the sensor by the headset unit).

For magnetic resonance applications, and other applications wherein (strong) magnetic or electric fields may be applied, the materials of the device and the electronics of the device and the circuitry of the device may especially be designed for such applications. For instance, electronics may be shielded from the external, e.g. with a Faraday cage. Further, especially materials may be applied that are MR compatible when the headset unit is to be applied in MR applications. MR compatible materials may e.g. include ABS and all other ferro-magnetic free materials.

The elements of the headset unit may be relatively basic. It is not necessary (though not excluded) to use complicated electronics and/or optics. For this reason, the headset unit may include be a relatively simple and light weight construction. Further, a substantial part of the headset unit may be constructed seamless. Such features also add to the user friendliness and facilitate e.g. efficient cleaning of the headset after use.

The headset unit may further comprise one or more camera(s) (especially physically associated with the headset unit). Alternatively or additionally, the headset unit comprising system may comprise a camera (not necessarily physically associated with the headset unit). The camera may be configured to capture images from the external of the headset unit. By providing such images to the display section, the user may (real time) experience the environment external from the headset unit. In specific embodiments, the control system may be configured to provide images from the camera(s), i.e. images from the environment, to the display sections in dependence of a sensor signal of a sensor comprised by the headset unit. For instance, when anxiety of the user would be detected, the control system may change to camera images to relax the user.

The invention further provides a method for providing visual content and optionally sound (to a user with a headset unit) as defined herein, the method comprising displaying visual content to one or both display sections and optionally providing sound to one or more of the ear units.

In also a further aspect the invention also provides a computer program product, which, when loaded on a processor, is configured to execute the method. In an embodiment, the computer program product can be stored on a storage medium, such as on a remote server, on a computer (see also above in relation to a headset unit comprising system), etc. The method may be executed in dependence of a sensor signal such as defined above.

A suitable material for transparent optics such as micro lenses, Fresnel lenses and variable lenses like the Alvarez lenses may e.g. poly methyl methacrylate (PMMA) (which appeared to be one of the best materials). Especially good refractive indices are in the range of 1.45-1.55, such as about 1.5, especially at about 600 nm. This may apply to the material of the Fresnel lenses, but may apply as well to the micro lenses or other lenses, or other optics that might be used in a light transmissive configuration.

With respect to the Fresnel lens, the SAG formula simulated focal length is 25-45 nm, such as especially 30-38 mm. Especially, the Fresnel lens is an aspherical lens, which may especially correct for spherical aberration caused by refraction towards the edges of the Fresnel lens. Further, especially the Fresnel lens has a diameter selected from the range of 40-60 mm, such as about 46-50 mm. The Fresnel lens is especially circular, though this is not necessarily the case. Such dimensions may especially accommodate the full field of view of the human eye in this near-eye vision solution. However, the lens is not necessarily cylindrical. Further, the Fresnel lens has especially in the range of 60-95, such as 65-90 grooves, like about 75. Less grooves than 65, such as less than 60 may lead to lower quality projections (and/or groove perception by the human eye) and a higher number of grooves, such as higher than 90, especially higher then 90 may lead to bulky lenses (and/or may produce more stray light). Hence, in embodiments the Fresnel lenses have a focal length selected from the range of 25-45 mm, have a number of concentric grooves selected from the range of 65-90, and wherein the Fresnel lenses comprise poly methyl methacrylate.

In yet a further embodiment, the Fresnel lens may also correct for a vertical-axis curved display providing a constant focal length over the entire field of view.

The herein described (near-eye vision) optics can especially be combined with one or two HD displays, based on LCD, LED or OLED, which may be flat or curved. This allows HD viewing enabling full immersion into the presented images with an about 180° field of view. These images can be experienced as stereoscopic, 3D and in VR presentations.

The compact dimensions and lightweight materials give an improved adherence in particular for use in healthcare applications. Build-in eye-monitoring and eye-tracking cameras with IR illumination contribute to scientific and diagnostic purposes.

An embedded audiovisual (AV) adapter may be used, which can be connected to an external interface which can transfer the selected data. This transfer can be wired, such as e.g. HDMI, or wireless, such as e.g. Bluetooth or DECT. Especially, the latter may be useful in hospital applications.

The invention allows the use of Fresnel lenses with mechanical axial and/or lateral adjustment for interpupillary distance (IPD) adjustment from 50 -75 mm and/or diopter adjustments per individual eye from −4+2.

### BRIEF DESCRIPTION OF THE DRAWINGS

Embodiments of the invention will now be described, by way of example only, with reference to the accompanying schematic drawings in which corresponding reference symbols indicate corresponding parts, and in which:

FIGS. 1a-1g schematically depicts some aspects and variants of the headset unit;

FIGS. 2a-2e schematically depict some embodiments, further variants and additional aspects;

FIG. 3 schematically depicts a 3D view of relevant elements of an embodiment of a headset unit;

FIG. 4 schematically depicts an embodiment of a Fresnel lens.

The schematic drawings are not necessarily on scale.

### DETAILED DESCRIPTION OF THE EMBODIMENTS

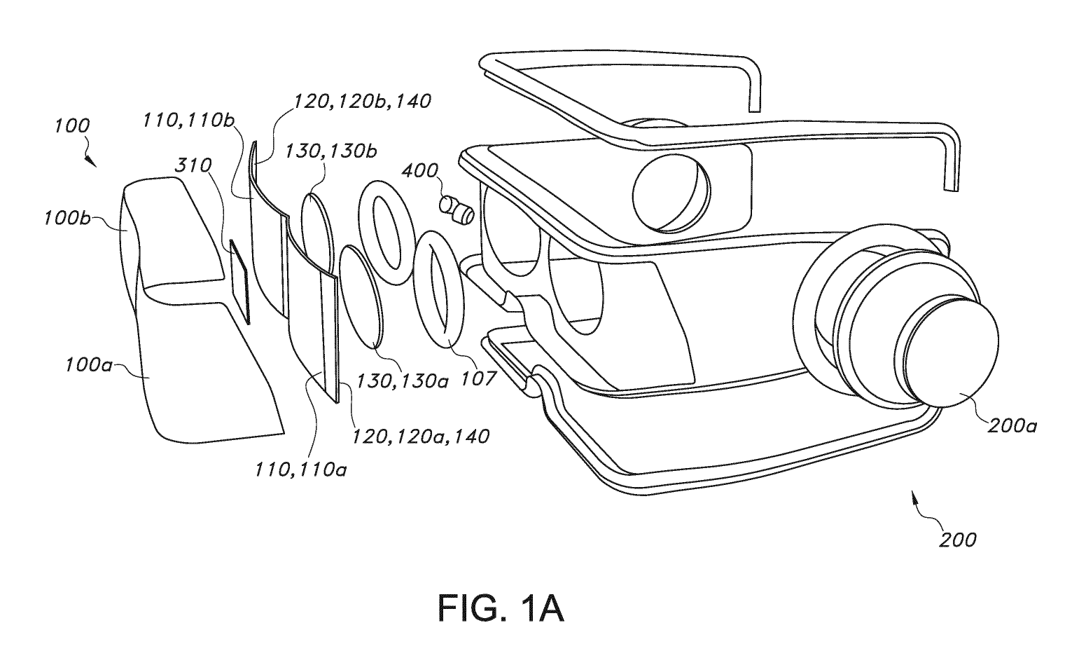

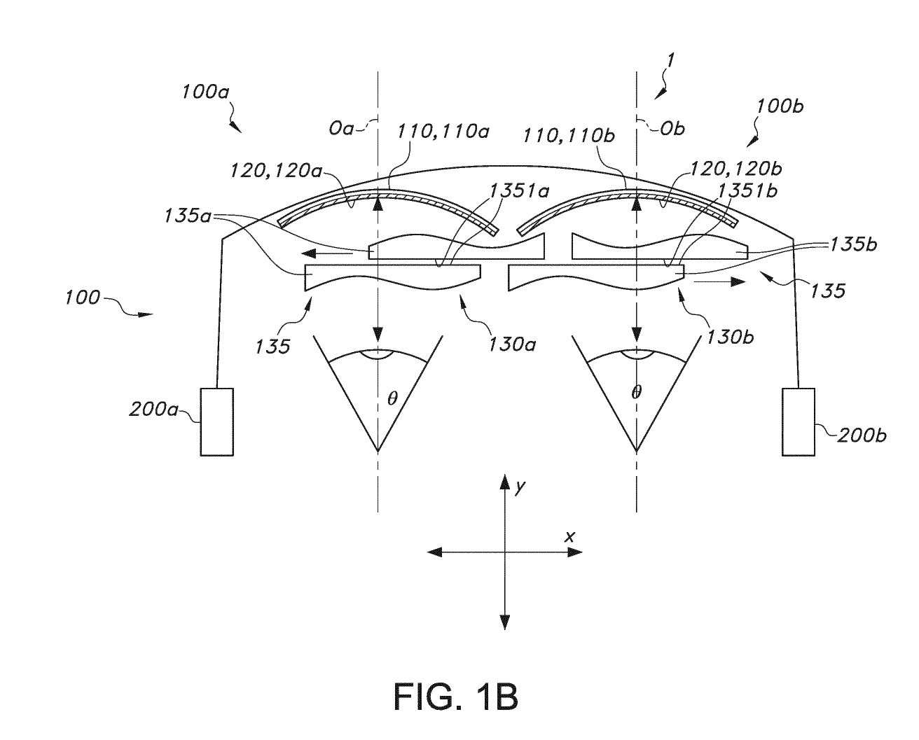

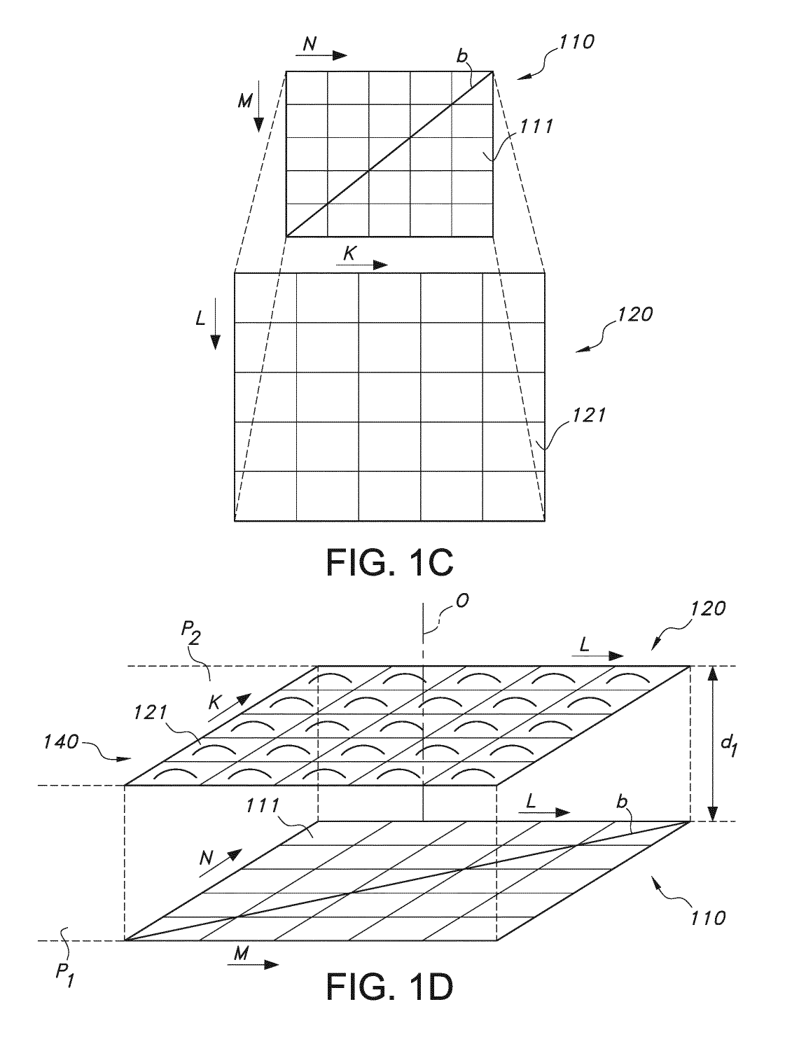

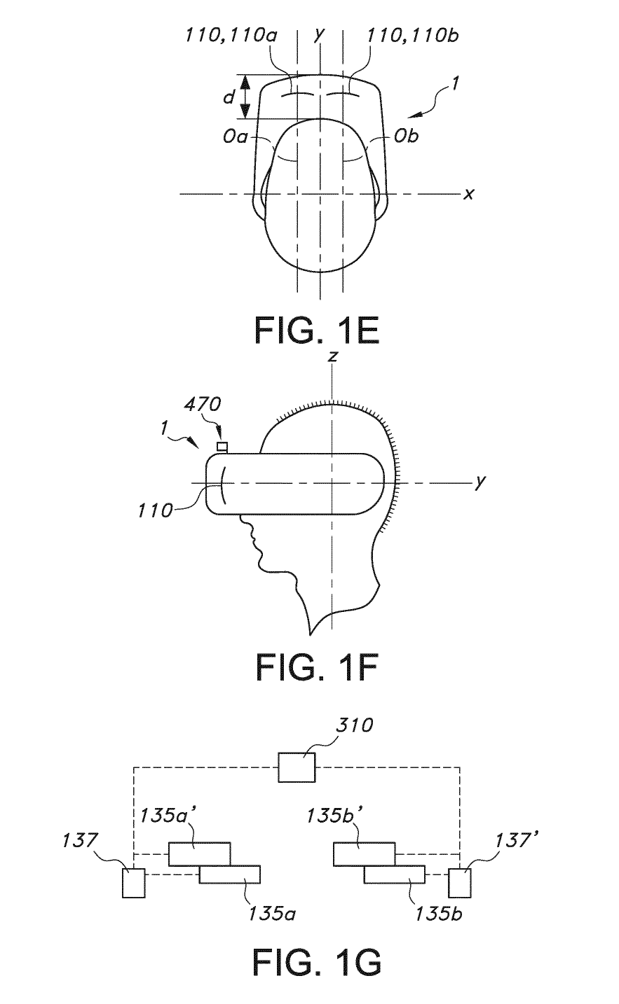

FIG. 1a schematically depicts a headset unit 1 comprising a pair of goggles 100 with an implemented video functionality and ear units 200. The pair of goggles 100 includes goggle elements 100a, and 100b, for each human eye. The headset unit may e.g. be provided in different dimensions, such as for infants, teenagers and adults.

The headset unit 1 is configured to substantially enclose the eyes of a human during use of the headset unit to prevent external light reaching the eyes of the human wearing said headset unit 1. For instance, one eye may only receive light from the respective display unit (see below), and substantially no cross-lighting between the two goggle elements 100a and 100b may occur. To this end, the headset 1 may also include isolating elements 107 (“facial cushions”) to isolate the goggle elements 100a,100b from each other such that no light escapes from one goggle element to the other.

The ear units 200 are configured to enclose the ears or to be plugged into the ears. Especially, the ear units 200 are configured to provide a sound signal to the ears. The sound signal may be provided from external via an internal control system 310. However, the internal control system may also substantially autonomously provide the sound signal to the ear unit, e.g. from a library of music and or movies.

The goggles 100 comprise display sections 110. A demo version included display sections 110 with 2560×1440 pixels. The headset unit 1 further comprises independently adaptable first optics 130 for dioptric adjustment. These are configured downstream for the display sections. The display sections 110 and the first optics 130 are configured to provide images to the eyes of the human wearing said headset unit 1 (adapted to the eyes of the user). Further, the headset unit 1 may comprise micro lens arrays 120 (see further also below) or another type of second optics. The second optics are indicated with reference 140, and may alternative include e.g. a Fresnel lens. References 110a and 110b refer to the display sections related to a first eye and to a second eye, respectively. They are herein also indicated as first display second and second display section. In analogy, also the first optics 110 are indicated in more detail with first optics 130a (first first optics) and first optics 130b (second first optics). Likewise, this nomenclature is applied for the second optics 120, etc.

As indicated above, the headset unit 1 may further comprises an internal control system 310, which is especially at least configured to control image content displayed on the display sections 110, but optionally also configured to provide a sound signal to the ears (with the aid of the ear units 200).

FIG. 1b schematically depicts a top view of the headset unit 1, wherein the independently adaptable first optics 130 for dioptric adjustment each comprise a set of Alvarez lenses 135. References 135a and 135b, and 135a′ and 135b′, respectively, indicate the Alvarez lens elements of the Alvarez lenses 135. The x-axis is defined parallel to a line from ear to ear. An y-axis is defined perpendicular to this line, and is parallel to a line perpendicular to the eyes. A z-axis (see FIG. 1f) is defined perpendicular to the x-axis and y-axis, and being parallel to a line through the body of a straight standing person from top to bottom. Note that the Alvarez lens elements of an Alvarez lens may be movable relative to each other (lateral arrow). Additionally, a movement in a direction to the eyes or from the eyes, i.e. parallel to the y-axis, may be possible. To this end, the headset unit may include a means for moving the first optics 130. The axis perpendicular to the eye can also be indicated as optical axis.

Referring again to the Alvarez lenses 135, they comprise each at least two lens elements 135a, 135b. The sides of these elements facing each other, indicated with references 1351a, 1351b, respectively, may substantially be flat. However, such flat side may optionally be provided with second optics, such as a micro lens array and/or a Fresnel lens. For instance, such second optics may be 3D printed on these sides

The distance between the eye and the display sections 110, indicated with reference a, may e.g. be in the range of 2-6 cm, especially 2-5 cm, such as 2.5-3 cm. This may lead to a total depth of at maximum 10 cm, such as in the range of 4-10 cm, like at maximum 8 cm see also FIG. 1e. The display sections 110 are configured in the headset unit 1 to provide a field of view angle θ to the eyes of at least 70°. Further, reference d indicates the thickness or depth of the device 100, which may be in the range of up to about 10 cm. Hence, the display section 110 are very close, within about 11 cm or less from the eyes. The latter distance may be a bit larger than the depth d, in view of the position of the eyes relative to the forehead, from which the thickness of the device 100 may be evaluated. Hence, as the display sections 110 are very close to the eyes, the device may herein also be indicated as near eye vision device.

References Oa and Ob indicate optical axes associated with the first optics 130 and/or second optics 120. Note that the first optics may e.g. be movable in a direction perpendicular to the optical axis and/or parallel to the optical axes (see arrows).

Referring to FIG. 1a, there is a sequence of kind of stack of display sections 110, micro lens array 120, and first optics 130. The former two, i.e. display sections 110, micro lens array 120, may physically be coupled. The first optics 130 may especially be arranged at a distance from the micro lens array 120, such as at a distance of about 10-40 mm. In yet a further embodiment, the two display section 110 may optionally be comprised in a single display including two separate display sections 110a,110b.

As shown in FIGS. 1c-1d the display 110 sections (each) comprise nxm pixels 111. Further, the headset unit 1 may comprises (two sets of) kxl micro lens arrays 120, comprising micro lenses 121, configured downstream of said display sections 110. The values of n and m independently are at least 100, and k and l independently are at least 100. In FIGS. 1c and 1d there is a non-zero distance (distance indicated with reference d1) between the micro lens array 120 and the display section 110. However, as indicated above, d1 may also be zero. When non-zero, d1 may be in the range of 1-3 mm. The display section 110 may have a diagonal b in the range of about 1-3″ (i.e. 1-3 inch), such as e.g. 2.6″ or 6″. Reference 140 indicates second optics, which here comprise the micro lens array 120. Here, both the display section 110 and the second optics 140, especially the micro lens array 120, are schematically depicted as having substantially flat cross-sectional planes P1 and P2, respectively. However, the display section 110 and/or the second optics 140 may have a curvature in one dimension or a curvature in two dimensions. For instance, the display section 110 and/or the second optics 140 may be curved along m or l and/or may be curved along n or k. As indicated above, especially at least the display section 110 has at least one curvature (see also FIGS. 1a, 1b, 1e, 1f and 3). Reference O indicates the optical axis (related to the second optics 140).

FIG. 1e schematically depicts a top view of a user wearing the headset 1. In this embodiment, the optional curvature of the display section 110 (110a,110b) is depicted. The display sections 110 comprise curved displays, having at least curvatures in one dimension y. For instance, the display sections 110 comprise flexible or curved displays. FIG. 1f schematically depicts that also another curvature may be available. Here, a side view of the user with headset 1 is schematically depicted, with a curvature relative to the z-axis. By way of example, the headset unit 1 in FIG. 1f further comprises a camera 470 (which may include a plurality of cameras). With the camera, the environment may be viewed. If desired, the user may switch to the images generated by the camera 470. For instance, the control system (not indicated in this drawing) may be based on sensor data switch the display content to the images generated by the camera. In this way, when anxiety would be detected, the user may be relaxed by seeing the surrounding of the user. This may relax the user.

FIG. 1g very schematically depicts an embodiment wherein the headset unit (only some parts essential for this drawing are depicted) further comprises an electronic device 137 configured to control the dioptric adjustment of the first optics. The electronic device 137 may e.g. be controlled by the internal control system 310. References 135a and 135b, and 135a′ and 135b′, respectively, indicate the Alvarez lens elements of the Alvarez lenses 135. The electronic device 137 is herein also indicated as means for moving.

Below, some examples of possible embodiments are schematically indicated in a table:

| Embodiment a1 | Embodiment a2 | Embodiment b1 | Embodiment b2 |
|---|---|---|---|
| Display section 110 | Display section 110 | Display section 110 | Display section 110 |
| Micro lens array 120 | Micro-lens array 120 | Fresnel lens 125 (on | Fresnel lens 125 |
| (on display section) | (remote from display | display section) | (remote from display |
| | section) | | section) |
| Adaptable first optics | Adaptable first optics | Adaptable first optics | Adaptable first optics |
| 130 | 130 | 130 | 130 |

| Embodiment c1 | Embodiment c2 | Embodiment c3 |
|---|---|---|
| Display section 110 | Display section 110 | Display section 110 |
| Adaptable first optics | Adaptable first optics | Adaptable optics |
| 130 with micro-lens | 130 with Fresnel lens | selected from micro- |
| array 120 integrated | 125 integrated in | lens array and |
| in Alvarez lens | Alvarez lens | Fresnel lens |

The numbering of the embodiments is only for the sake of clarity, and is not related to Figures provided herein.

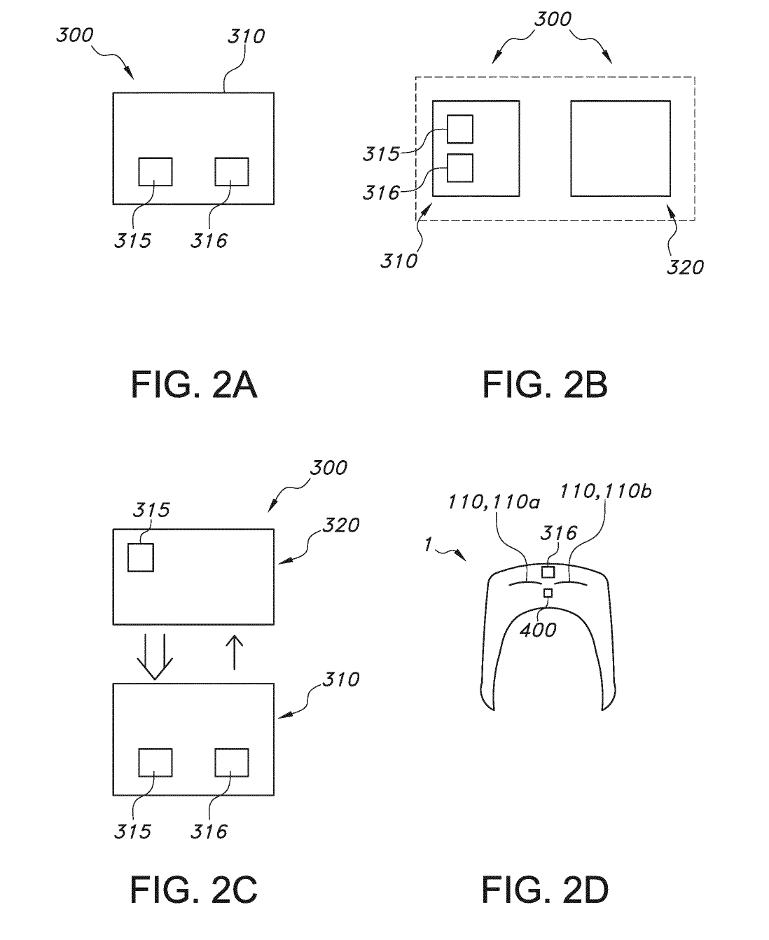

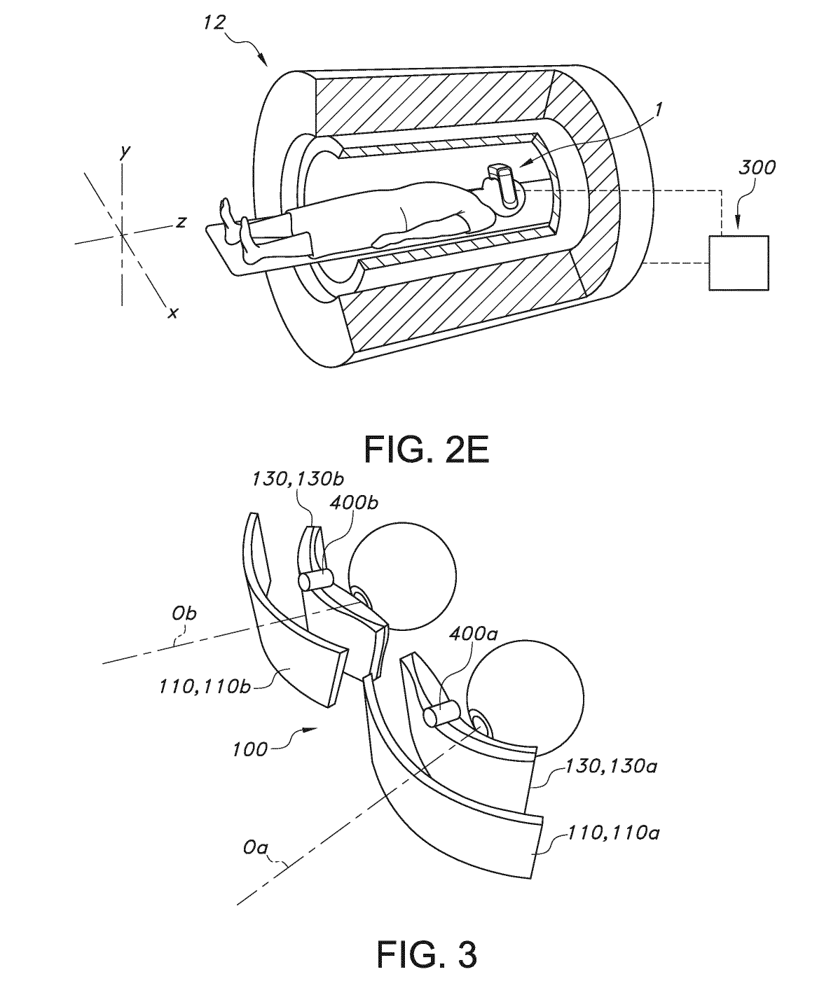

FIGS. 2a-2c schematically depict a non-limiting number embodiments of a control system 300 for at least controlling the contents displayed on the display elements (see other drawings). Amongst others, the internal control system 310 may (substantially) exclusively be used for this purpose. To this end, the internal control system may further comprising a memory 315 configured to store one or more of video information and audio information, wherein the memory 315 is functionally coupled with the control system 310. The headset unit (not depicted in this drawing) may further comprise a transmitter unit 316, configured to transmit a signal from a sensor 400 or the internal control system 310 to an external control system 320 and/or to receive one or more of video information and audio information from the external control system 320 for displaying on the display sections 110 and for providing to the ear units 200, respectively. Here, by way of example the transmitter 316 is functionally integrated in the internal control system 310.

FIG. 2b shows a control system including two functionally coupled elements comprising at least the internal control system 310 and an external control system 320. Further, the internal control system 310 is functionally connectable to an external control system 320. As indicated above, the headset unit 1 may further comprise a transmitter unit 316, configured to transmit a signal from a sensor 400 or the internal control system 310 to an external control system 320 and/or to receive one or more of video information and audio information from the external control system 320 for displaying on the display sections 110 and for providing to the ear units 200, respectively. In fact, this embodiment may relate to two control systems on separate devices, but communicating with each other or may refer to a single control system, with subordinate control systems.

FIG. 2c schematically depicts an embodiment of the control system 100 wherein the external control system 320 controls the internal control system. The internal control system 310 may functionally connectable to the external control system 320.

FIG. 2d schematically depict an embodiment of the headset 1 further comprising a sensor 400 configured to sense eye behavior of one or more eyes of the human wearing the headset unit 1, and/or one or more other user parameters, wherein the sensor is configured to provide a corresponding sensor signal to a control system 300, especially an external control system 320 (not shown). To this end the headset unit 1 may further comprise a transmitter unit 316 configured to transmit a signal from a sensor 400 to an external control system 320. Alternatively or additionally, the transmitter unit may also be configured to transmit a signal of the internal control system 310 to the external control system 320 (see also above).

FIG. 2e very schematically depicts a sensor setup 10 comprising a sensing apparatus 12 configured to sense a body part of a human, the sensor setup 10 further comprising a control system 300 configured to control the headset unit 1 as defined herein, or a sensor setup 10 comprising a sensing apparatus 12 configured to sense a body part of a human, the sensor setup 10 further comprising a control system 300 configured to control the headset unit 1 as defined herein and the sensing apparatus 12, wherein the headset unit 1 comprises a sensor 400 to measure a user parameter of a user wearing the headset unit 1, and wherein the control system 300 is configured to control the sensing apparatus 12 as function of the user parameter. In an embodiment, the sensor setup 10, more precisely the sensing apparatus 12, is configured to sense a body part of a human as function of one or more of (i) video information and (ii) audio information, displayed on the display sections and provided to the ear units 200, respectively, during use of the sensor setup 10 and headset unit 1. For instance, the sensor setup 10 may comprise an MRI device (as sensing apparatus 12).

For a near-eye vision application (image presentation about <45 mm from the human eye lens) a plurality of different type of optics was investigated. Amongst others, the following were especially investigated:
1. A traditional flat-curved lens which would be the best alternative but excluded for its bulky form;
2. A micro-lens array which has the right dimensions and magnification potential but due to substantial cross-talk between the individual lenses, it cannot provide sufficient quality.
3. A Fresnel lens which has the right dimension and magnification potential and offers sufficient quality if calculated correctly.

All these options can be combined with variable optics, such as Alvarez lenses. However, in the simulations these variable optics were not included.

The material of the optics of these three options can e.g. be PMMA with an index of refraction of about 1.49 at 600 nm.

With respect to the Fresnel lens, the SAG formula simulated focal length is 30-38 mm which in combination with a distance between the eye-lens and display of 30-45 mm offers good focus for diopters from −4 to +2. The best results were achieved with an optimized a-spherical lens with a diameter of 48 mm. Further, the simulation conclusions provided the best results with 75 concentric grooves, with individual corrections for the groves further to the edge. The simulation shows further optimal clarity no color-shift and chromatic aberrations with acceptable image quality towards the edge.

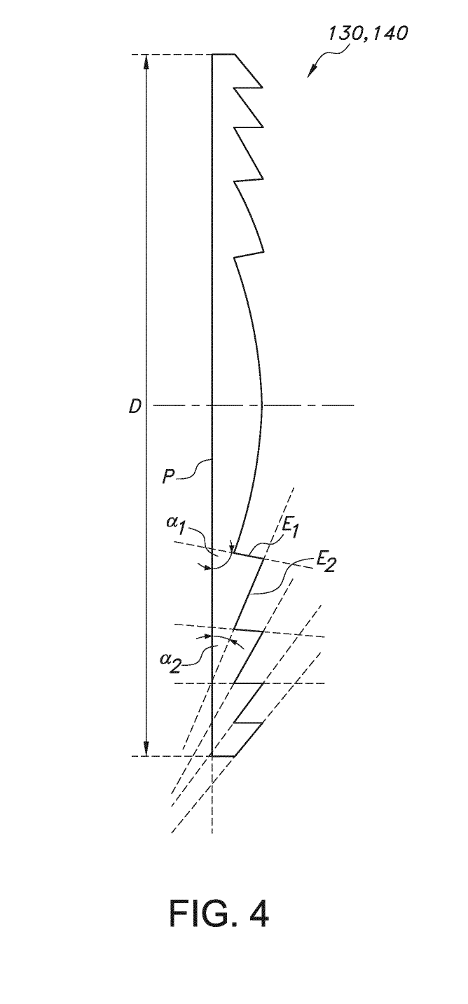

FIG. 4 schematically depicts a Fresnel lens that might be used as first optics 130 or second optics 140 (if available). Reference D indicates the diameter; reference G indicates a groove, of which (thus) about 75 may be available. The grooves G are defined by first edges E1, having angles al with a virtual plane P through the lens (plane is dashed), which are selected from the range of 80° to about 90°. The grooves G are further defined by second edges E1, having angles α2 with a virtual plane P through the lens which are selected from the range of about 20-60°. Note that the back side, here coinciding with the virtual plane P, is not necessarily flat, but may be curved, such as convex or concave.

In embodiments, with the aid of the SAG formula, the overall performance of the bulk lens may be determined. Then the bulk lens is divided in grooves. In specific embodiments, all grooves are shifted in order to make a thin lens (Fresnel lens). Then corrections can be made, per groove individually. This is done in the SAG formula using the α1, α2 etc. correction factors.

The term “substantially” herein, such as in “substantially consists”, will be understood by the person skilled in the art. The term “substantially” may also include embodiments with “entirely”, “completely”, “all”, etc. Hence, in embodiments the adjective substantially may also be removed. Where applicable, the term “substantially” may also relate to 90% or higher, such as 95% or higher, especially 99% or higher, even more especially 99.5% or higher, including 100%. The term “comprise” includes also embodiments wherein the term “comprises” means “consists of”. The term “and/or” especially relates to one or more of the items mentioned before and after “and/or”. For instance, a phrase “item 1 and/or item 2” and similar phrases may relate to one or more of item 1 and item 2. The term “comprising” may in an embodiment refer to “consisting of” but may in another embodiment also refer to “containing at least the defined species and optionally one or more other species”.

Furthermore, the terms first, second, third and the like in the description and in the claims, are used for distinguishing between similar elements and not necessarily for describing a sequential or chronological order. It is to be understood that the terms so used are interchangeable under appropriate circumstances and that the embodiments of the invention described herein are capable of operation in other sequences than described or illustrated herein.

The devices herein are amongst others described during operation. As will be clear to the person skilled in the art, the invention is not limited to methods of operation or devices in operation.

It should be noted that the above-mentioned embodiments illustrate rather than limit the invention, and that those skilled in the art will be able to design many alternative embodiments without departing from the scope of the appended claims. In the claims, any reference signs placed between parentheses shall not be construed as limiting the claim. Use of the verb “to comprise” and its conjugations does not exclude the presence of elements or steps other than those stated in a claim. The article “a” or “an” preceding an element does not exclude the presence of a plurality of such elements. The invention may be implemented by means of hardware comprising several distinct elements, and by means of a suitably programmed computer. In the device claim enumerating several means, several of these means may be embodied by one and the same item of hardware. The mere fact that certain measures are recited in mutually different dependent claims does not indicate that a combination of these measures cannot be used to advantage.

The invention further applies to a device comprising one or more of the characterizing features described in the description and/or shown in the attached drawings. The invention further pertains to a method or process comprising one or more of the characterizing features described in the description and/or shown in the attached drawings.

The various aspects discussed in this patent can be combined in order to provide additional advantages. Further, the person skilled in the art will understand that embodiments can be combined, and that also more than two embodiments can be combined. Furthermore, some of the features can form the basis for one or more divisional applications.

1. A headset unit comprising (i) a pair of goggles with an implemented video functionality and (ii) ear units, wherein the headset unit is configured to substantially enclose the eyes of a human during use of the headset unit to prevent external light reaching the eyes of the human wearing said headset unit, wherein the ear units are configured to enclose the ears or to be plugged into the ears, wherein the ear units are configured to provide a sound signal to the ears, wherein the goggles comprise display sections, wherein the headset unit comprises first optics and optional second optics, wherein the display sections, the first optics and the optional second optics, are configured to provide images to the eyes of the human wearing said headset unit, wherein the first optics or the optional second optics comprise Fresnel lenses.

2. The headset unit according to claim 1, wherein the display sections each comprise n×m pixels, and wherein n and m independently are at least 600, and wherein k and l independently are at least 150.

3. The headset unit according to claim 1, wherein the headset unit further comprises said second optics, wherein the second optics comprises two sets of k×l micro lens arrays, comprising micro lenses, configured downstream of said display sections, respectively.

4. The headset unit according to claim 1, wherein the headset unit comprises independently adaptable first optics for dioptric adjustment, and wherein the independently adaptable first optics for dioptric adjustment each comprise a set of Alvarez lenses.

5. The headset unit according to claim 1, wherein the display sections each comprise n×m pixels, wherein the headset unit further comprises said second optics, wherein the second optics comprise said Fresnel lenses, configured downstream of said display sections, respectively, and wherein the independently adaptable first optics for dioptric adjustment each comprise a set of Alvarez lenses, wherein n and m independently are at least 100, and wherein k and l independently are at least 1200.

6. The headset unit according to claim 1, wherein the headset unit has a maximum depth of 10 cm and wherein the display sections are configured in the headset unit to provide a field of view angle to the eyes of at least 70°.

7. The headset unit according to claim 1, wherein each display section comprises a display selected from the group consisting of a liquid crystal display, a light emitting diode display, an organic light emitting diode display, an active-matrix organic light-emitting diode display, and an electric paper display.

8. The headset unit according to claim 1, wherein the display sections comprise curved displays, having at least curvatures in one dimension, and wherein the display sections comprise flexible displays.

9. The headset unit according to claim 1, wherein the headset unit further comprises an internal control system configured to control image content displayed on the display sections.

10. The headset unit according to claim 9, wherein the ear units are configured to provide sound to the human wearing the headset unit, and wherein the internal control system is configured to control the sound provided by the ear units.

11. The headset unit according to claim 9, further comprising a memory configured to store one or more of video information and audio information, wherein the memory is functionally coupled with the control system.

12. The headset unit according to claim 9, further comprising a sensor configured to sense eye behaviour of one or more eyes of the human wearing the headset unit, wherein the sensor is configured to provide a corresponding sensor signal to a control system.

13. The headset unit according to claim 9, further comprising a transmitter unit, configured to transmit a signal from a sensor or the internal control system to an external control system and/or to receive one or more of video information and audio information from the external control system for displaying on the display sections and for providing to the ear units, respectively.

14. The headset unit according to claim 1, wherein the Fresnel lenses have a focal length selected from the range of 25-45 mm, have a number of concentric grooves selected from the range of 65-90, and wherein the Fresnel lenses comprise poly methyl methacrylate.

15. The headset unit according to claim 1, wherein the first optics comprise Alvarez lenses, wherein the Fresnel lenses are integrated.

16. A sensor setup comprising a sensing apparatus configured to sense a body part of a human, the sensor setup further comprising a control system configured to control the headset unit according to claim 1.

17. The sensor setup according to claim 16, wherein the sensor setup is configured to sense a body part of a human as function of one or more of (i) video information and (ii) audio information, displayed on the display sections and provided to the ear units, respectively, during use of the sensor setup and headset unit.

18. The sensor setup according to claim 16, wherein the sensor setup comprises an MRI device.

19. The sensor setup according to claim 16, wherein the control system is configured to suppress noise generated by the sensing apparatus by providing a sound suppression signal to the ear units.

20. The sensor setup according to claim 16, wherein the headset unit comprises a sensor to measure a user parameter of a user wearing the headset unit, and wherein the control system is configured to control the sensing apparatus as function of the user parameter.
